(19) United States
(12) Patent Application Publication
(10) Pub. No.: US 2024/0327970 A1
(43) Pub. Date: Oct. 3, 2024

(54) COATING METHOD AND COATING CONTAINING SILICON

(71) Applicant: Ralph DOMNICK, Nordhorn (DE)

(72) Inventor: Ralph DOMNICK, Nordhorn (DE)

(21) Appl. No.: 18/259,554

(22) PCT Filed: Dec. 23, 2021
(86) PCT No.: PCT/EP2021/087583

§ 371 Date: Jan. 5, 2024

(30) Foreign Application Priority Data
Dec. 29, 2020 (DE) 10 2020 135 061.9

(51) Int. Cl. C23C 14/04; C23C 14/14; C23C 14/28; H01M 4/86

(52) U.S. Cl. CPC C23C 14/048; C23C 14/14; C23C 14/28; H01M 4/8621; H01M 4/8631

(57) ABSTRACT

The invention relates to a method for coating a substrate (2), comprising the following steps:—providing a transparent carrier film (21) coated with silicon,—positioning the side of the carrier film (21), which is coated with silicon, on a surface of the substrate (2),—rasterized impingement of the coated carrier film (21) with laser radiation, whereby silicon is detached point by point from the carrier film (21) and is deposited as a porous, rough, superhydrophilic layer (6) on the substrate (2).

The invention relates to a coating method in which material is transferred from a carrier film onto a substrate with the aid of laser radiation. Furthermore, the invention relates to a porous coating containing silicon.

DE 10 2018 109 337 A1 discloses a method for the manufacture of a transparent, electrically conductive oxide coating, in particular an indium tin oxide coating. In the context of that method, a transparent carrier object, which has multiple layers, including tin, is placed on a substrate and material is then transferred from the carrier object onto the substrate. The indium tin oxide layer (ITO layer) which is thus produced on the substrate has liquid-repellent properties which endure even when the coating is stressed mechanically.

A method for coating a substrate described in WO 2016/055166 A2, which is also operated with the aid of a laser, envisages coating a carrier film produced from polyethylene terephthalate (PET). Coating material which is to be transferred onto a substrate by laser is deposited on the carrier film by physical vapour deposition in a step of the method which precedes the laser transfer. The laser radiation is carried out in a manner such that only part of the coating material is transferred from the carrier film onto the substrate.

In a method for the laser-induced transfer of material described in US 2002/0098614 A1, a laser is located outside a chamber in which the laser transfer takes place. The chamber may be a vacuum container or a container filled with inert gas.

A multi-layered laser transfer film for permanently inscribing components is described in detail in WO 03/080334 A1. In this case, in addition to an adhesive layer, at least two pigment layers are also located on a carrier layer, wherein one of the pigment layers is a glass flux pigment and the second pigment layer contains a laser-sensitive pigment. Possible carrier materials which are cited include PVC films and PET films.

EP 1 954 507 B1 concerns the laser transfer of security features. It proposes that, in order to label products with features that protect against counterfeiting, security features which cannot be copied are incorporated into a layer system and transferred onto the product by the laser radiation. In the context of laser transfer, laser energy should be absorbed by a laser-sensitive material, wherein this could be carbon or a metal oxide, for example.

EP 1 942 961 B1 describes a method for the manufacture of an open-pored biocompatible surface layer for an implant. In the context of that method, titanium particles are coated with a sintering aid which may be silicon or cobalt.

The objective of the invention is to further develop the coating of a substrate with a porous silicon-containing material of the prior art in the direction of a high process reliability and product quality as well as in the direction of multiplying its potential applications.

In accordance with the invention, this objective is achieved by means of a method for coating a substrate in accordance with claim 1. The objective is also achieved by means of a coating which completely or partially covers a substrate in accordance with claim 20. Embodiments and advantages of the invention described below in conjunction with the device, i.e. the coating, apply analogously to the coating method, and vice versa.

The coating method comprises the following steps:
providing a transparent carrier film which is coated with silicon,
positioning the side of the carrier film coated with silicon on a surface of the substrate,
applying rasterized laser radiation to the coated carrier film, whereby silicon is detached from the carrier film point by point and is deposited on the substrate as a porous, rough, superhydrophilic layer.

The superhydrophilic property of the layer means that a droplet of water applied to the layer spreads immediately, i.e. the contact angle is 0°. In particular, the contact angle may be imaginary. A droplet of water applied to the superhydrophilic layer could, for example, yield an imaginary contact angle of 6°. Reference should be made to the document WO 2013/087073 A2 for background information regarding imaginary contact angles in respect of hyperhydrophilic surfaces.

A particularly suitable method for depositing silicon on the carrier film which is principally known from the prior art is physical gas phase deposition (PVD=physical vapour deposition). The starting material for sputtering or evaporation deposition may be a pure silicon target or, in the case of sputtering, a target doped with a small proportion of aluminium, for example. Irrespective of how the silicon-containing starting layer is deposited on the carrier film, the laser transfer layer which forms on the substrate is more adhesive and more porous than the starting layer.

A PET film may in particular be used as the carrier film. As an alternative, the use of a carrier film produced from a different plastic, for example PVC, PMMA or PE, as well as the use of a carrier plate produced from glass may be considered. Typically, the carrier object, in particular in the form of a carrier film, is a few μm or a few tens of μm to a few hundreds of μm thick. As an example, the thickness of a transparent PET carrier film is in the range from 6 μm to 125 μm. In particular, the carrier film may be in the form of rolled goods, wherein the coating is applied with the aid of a roll-to-roll coater, i.e. using roll-to-roll technology. The documents EP 2 527 048 B1, DE 10 2010 048 984 A1 and DE 10 2015 109 809 A, for example, provide indications of roll-to-roll coating processes.

A glass carrier plate typically has a thickness of one millimetre up to a few millimetres. The thickness of the silicon which is located on the carrier material, which is either rigid or flexible, is in the range from 300 nm to 2 μm or 3 μm, in particular a thickness of approximately 700 nm, for example.

The superhydrophilic silicon-containing layer may have a microstructure which is not visible to the naked eye, which is produced by directing the laser radiation onto the carrier film in the form of individual raster dots. In this regard, each raster dot of the laser beam has a standardized diameter which is defined by the fact that 68.27% of the irradiated power lies inside a circle with the standardized diameter. The mean distance between two adjacent raster dots is preferably at least 125% and at most 250% of the standardized diameter.

The layer produced on the substrate by rasterized laser radiation has an irregular thickness, wherein regions with a smaller thickness are surprisingly at locations irradiated by the maximum intensity of the laser beam. This means that the pattern inscribed by the regions with smaller thickness corresponds to that pattern which is inscribed by the laser beam which approximates a point by point operation, i.e. the raster dots. Between the regions of smaller thickness inscribing the pattern of the raster dots, an intermediate region of the coating is formed in which silicon which has been deposited on the substrate is also located. In the intermediate region, the coating is not only thicker, but also rougher than in the aforementioned regions, which typically form a regular pattern of dots. In particular, the intermediate region may comprise a plurality of individual needles which are located on the substrate as individual spikes. In the extreme case, the entire network-like intermediate region is exclusively formed by such needles. The needles may be interpreted as splashes of material which are located on the substrate exclusively or substantially outside the comparatively dense regions of low roughness and thickness produced by intensive laser radiation.

The individual circular regions with low roughness and thickness, which are also known as laser spots, have a diameter of 22 to 25 μm, for example. The distance between two laser spots is 33 to 43 μm, for example, measured between the central points of the laser spots. Correspondingly, the minimum intermediate region width between two laser spots is of the order of just under 10 μm to just over 20 μm. The thickness of the layer in the intermediate region is, for example, at least twice, in particular at least three times the layer thickness in the regions with low roughness and thickness disposed in a rasterized pattern.

Irrespective of which geometric form the rasterization which can be seen inside the superhydrophilic layer inscribes, coating parameters within this layer can vary. Furthermore, at least one further sub-area of the substrate may adjoin the sub-area of the substrate which is configured as a porous, superhydrophilic, micro-structured layer, wherein the adjoining sub-area, even in cases in which it is also exclusively or substantially coated with silicon, has poorer hydrophilic properties compared with the hydrophilic coated sub-area. Similarly, it is possible for a completely differently coated or an uncoated sub-area to adjoin the superhydrophilic coated sub-area. In all cases, an abrupt variation in the hydrophilic properties of the substrate surface may be present at a boundary between the different sub-areas.

In typical procedures for the method, silicon which is predominantly in the liquid form is transferred onto the substrate by the laser beam acting on the carrier film in a rasterized manner. As an example, for this material transfer, a laser beam with a power of 1.0 to 6.0 W, a frequency of 10 to 200 kHz, a laser speed of 500 to 4000 mm/s and a laser line separation of 0.02 to 0.3 mm is used.

The porous superhydrophilic silicon coating on the substrate in the form of a laser transfer layer may be arranged in the form of any pattern which is visible to the naked eye. As an example, such a pattern may be produced on the substrate as a striped pattern. Similarly, it is possible, for example, to apply the laser transfer layer as text, graphics or indeed as an all-over pattern, i.e. uniformly over a large region. In all cases, the layer surface may in particular be matt or rough. In many embodiments, the laser transfer layer appears as a brown layer on both the front and on the rear sides, provided that the substrate is transparent. Depending on the thickness, structure and exact composition of the layer, in particular, it may provide complete coverage or be slightly translucent.

Irradiation of the carrier film under atmospheric conditions is possible over a very wide range of possible laser parameters. Depending on the parameter settings for the laser radiation, during the transfer from the carrier film onto the substrate, silicon may react with components of the air in a manner such that a layer based on silicon is formed on the substrate which has a proportion of oxygen of 1% to 10%, given as the % by weight.

Furthermore, instead of using a carrier film which is exclusively coated with silicon, a carrier film on which a SiOₓN_{y} layer is formed may be used. In this regard, x is in particular in the range from 0.05 to 0.3 and y is in the range from 0.05 to 0.4. In addition to the SiOₓN_{y} layer, adjoining the SiOₓN_{y} layer, there may be a metallic layer a few nanometres thick on the carrier film, for example 1 nm to 20 nm, in particular 2 nm to 10 nm. This layer may be a layer produced from titanium, for example. In each case, because of the oxygen and nitrogen content, the coating which is initially on the carrier film can specifically produce silicon suboxides, silicon subnitrides and silicon suboxinitrides. In order to transfer material from the carrier film onto the substrate, including any chemical reactions, in particular with oxygen of the air, a very wide variety of conventional lasers with wavelengths in the range from 300 nm to 1400 nm may be used.

By adjusting the laser parameters during the coating process, coating parameters within the layer which is produced can be specifically varied. In particular, both hydrophilic and also hydrophobic coating regions may be produced by adjusting laser parameters during the coating process in a geometrically defined manner, in particular clocking and power of the laser, as well as the duration of the laser pulses and the separation of laser dots or lines. In this regard, a hydrophobic coating region can in particular be produced with a laser speed of less than 500 mm/s and a laser line separation of more than 0.3 mm.

The superhydrophilic silicon-based layer can be over-coated by repeatedly utilising a carrier film during one and the same coating procedure. The layer thickness is increased by the over-coating, wherein a previously unused region of the carrier film is always used, i.e. even in the case of multiple over-coating, each over-coating procedure exclusively uses as-yet unused regions of the carrier film.

As a supplement or as an alternative to over-coating, other supplemental upstream or downstream steps of the method may be carried out, and so numerous coating variations can be produced thereby. As an example, the porous rough superhydrophilic layer may be applied to a substrate in combination with a hydrophobic indium tin oxide layer which is known per se, which can also be deposited by laser transfer from a coated film.

In addition, the combined application of a superhydrophilic laser transfer layer and a PVD layer at different times is possible. The layer to be produced in the PVD (physical vapour deposition) process may be applied here to the workpiece to be coated under vacuum conditions in a step of the method which is downstream of the laser transfer.

In an alternative variation of the method, a further carrier film is provided in addition to the carrier film on which the layer of silicon is located, from which the superhydrophilic coating of the substrate is produced by laser transfer. On this further carrier film is a layer deposited using the PVD process, the composition thereof being different from said silicon layer located on the first carrier film. The further carrier film is employed after the porous laser transfer layer has already been produced on the substrate. In order to transfer the PVD layer from the further carrier film onto the workpiece which is already at least partially coated with a porous layer, a laser transfer method, preferably under atmospheric conditions, may again be used.

Finally, it is also possible to apply the porous, rough superhydrophilic layer to only a sub-area of the substrate, while a surface region which is less hydrophilic compared with the porous layer of the substrate remains uncoated. The superhydrophilic properties are particularly apparent when the coating is applied in stripes and loaded with water. If, for example, an 8 mm wide region of coating is loaded with water, then the water can pile up to a height of 4 mm without flowing into the adjacent uncoated regions. The fact that the water is retained can be explained as being due to the enormously high surface energy of the lasered silicon layer.

In principle, there are no limits to the geometry of the carrier film; if, for example, the inside of a transparent tube is to be provided with a superhydrophilic coating, then a tubular carrier film is used which is coated with silicon on its outside. The carrier film configured as a sleeve is introduced into the transparent tube which is to be provided with a superhydrophilic coating on its inside and is inflated inside the tube, so that the silicon layer comes into contact with the inner wall of the tube. The transfer of silicon onto the inner wall of the tube is carried out by laser radiation which passes from outside, through the wall of the tube and onto the sleeve.

It is also possible to coat items which have an external surface that describes a non-unrollable surface. In this case, a shrink sleeve coated with silicon on its inside is suitable as the carrier film and is drawn over the workpiece with the non-unrollable surface to be coated, wherein prior to laser transfer, the shrink sleeve is brought into contact with the workpiece by heating.

Irrespectively of the geometry of the item to be coated, the superhydrophilic layer typically has a porosity of at least 5% and at most 40%. In this regard, the porosity is defined as the fraction of voids in the material. In the case of the cited porosity limits of 5% and 40%, the density of the layer therefore corresponds to 95% or 60% of the density of the raw material.

The superhydrophilic silicon layer can not only be deposited on smooth surfaces, in particular ceramic or metallic surfaces, but also on fibrous materials. In particular, the superhydrophilic layer may be deposited onto paper or cardboard. It is also possible to apply the superhydrophilic silicon layer by laser transfer onto plastics, textiles, stone or wood. The fact that the layer transfer is actually possible with a low laser power which just leads to melting of the silicon layer is also of particular advantage, so that the substrate surface is not compromised, even with very temperature-sensitive materials, in particular with organic materials or materials with organic components.

Other applications of the superhydrophilic layer which may be mentioned are electrochemical products, catalysts as well as solar cells. In each of these cases, the large surface area which is provided by the coating plays a role. In fuel cells and redox flow cells, a particularly high power density can be obtained thereby. In particular, in a fuel cell, the superhydrophilic layer may be found on a membrane electrode unit, electrode and/or bipolar plate.

In the case of batteries, a porous layer with properties which can be precisely adjusted in the coating process, whereby changes in the properties can be made on the smallest scale, if necessary on a sub-millimetre scale, provides the opportunity for obtaining products with locally different space charges inside the electrochemical product concerned. Thus, boundary regions between p-materials and n-materials can be designed which differ greatly in their charge compared with conventional solutions; with the aid of the larger potential difference which is intended, this contributes significantly to a compact design and high power density.

Regarding catalytically supported reactions carried out with the aid of the superhydrophilic silicon-based layer, temperature stability also plays a role, depending on the type of reaction. In typical embodiments, the porous superhydrophilic layer is stable at temperatures of up to 600° Celsius. Furthermore, the layer is abrasion-resistant, sterilizable, extremely adhesive and UV-stable. The layer can be wiped with a cloth without damaging it using conventional pH-neutral, acidic or basic cleaning agents, in particular household cleaners.

The antimicrobial effectiveness of the superhydrophilic silicon-based layer produced by laser transfer has been shown to be particularly useful. In tests, the test pathogen Staphylococcus epidermis DSM 18857 was applied to substrate surfaces coated with this layer. The test was carried out in accordance with ISO 22196-2007 (measurement of antibacterial activity on plastic surfaces) and showed that 24 hours after the bacteria-containing liquid film was applied, a sufficient antimicrobial activity was exhibited, i.e. more than 99.99% of the pathogens had been killed in the cited time period.

Catalytic, not necessarily photocatalytic properties of the porous layer primarily constructed from silicon are also useful. This is of particular importance with solar cells. The catalytic properties also mean that it can be used in order to separate water into hydrogen and oxygen. Surprisingly, a catalytic property of the layer can be observed even without UV light. Gas bubbles form rapidly after applying distilled water to the layer. There is a significant difference here from the known photocatalytic production of hydrogen, i.e. splitting water molecules under the influence of photons. Background information in this regard can be found in the following dissertation: Sarah Saborowski: Photokatalytische Wasserstoffgewinnung an SOLECTRO®-Titandioxidschichten [Photocatalytic hydrogen production on SOLECTRO® titanium dioxide layers], Chemisch-Geowissenschaftliche Fakultat der Friedrich-Schiller-Universitst Jena, 2010.

Finally, reference is made to EP 0 931 855 B1, which concerns the production of hydrogen from water with a photocatalyst-electrolysis hybrid system.

In order to investigate the catalytic activity of the silicon-containing layer of the application, further tests were carried out with methylene blue. After applying methylene blue to the layer, it decolorized within a few minutes. Even after re-applying methylene blue several times, the same effect was obtained every time without the decolorization weakening; the surface was cleaned with isopropanol after every ten test cycles.

The extremely large surface area of the layer produced by the laser transfer is of essential importance to the very pronounced catalytic activity of the layer, be it in the decomposition of water molecules or in other cases. The layer is structured in the manner of what is known as a solid powder, onto which water or other molecules is dissociatively chemisorbed, so that the activation energy for the decomposition of the molecules concerned is reduced.

The optical properties of the superhydrophilic silicon-based layer depend on the exact composition of the layers. In many cases, it is a brownish, semi-transparent layer. If spectacle lenses are coated with the layer, in preferred embodiments, a reduced transmission in the blue, green and yellow wavelength range as well as a blocking action in the UV range is obtained. Because of the significantly different influence on red and blue light, spectacle lenses coated with the porous silicon layer are of great assistance to people with red-green impairment. Depending on the extent of the visual impairment, coating the spectacle lenses would enable a person to make a distinction between red and green more easily, or even be able to instantly distinguish between these colours.

An application of the porous silicon layer in the case of mirrors may also be considered if the reflectance is adjusted in a suitable manner. A high reflectance can in particular be obtained by over-coating. The superhydrophilic properties, which ensure that no water droplets form on the surface, constitute a general advantage for both mirrors and spectacle lenses, independently of the optical properties.

The porosity of the superhydrophilic layer may also enable liquid transport by the capillary effect. By means of this effect, liquid, in particular water, can be brought from a low level to a higher level and transferred into the gas phase at the high level, for example by means of light. Because the layer in the upper region of the substrate subsequently dries, conveying of the liquid by capillary action can be continued over any length of time.

In contrast to known products, in particular based on TiO₂, the superhydrophilic properties of the layer in accordance with the application are permanently retained without needing to be activated by light, in particular UV light. The layer is suitable, inter alia, for use in decorative or other items where the formation of water droplets or the visibility of fingerprints needs to be avoided. The capillary effect associated with the superhydrophilic properties can also be exploited in order to guide water specifically onto routes which have been applied to the surface of items in the form of the superhydrophilic layer and which almost act as tracks on which the water flows.

Evaporation of liquid on the surface of the layer is in principle of use in any liquids as long as the temperatures at which the coated substrate is used are matched to the properties of the liquid. The coated substrate may be used, inter alia, in order to dispense fragrances contained in liquids into the environment.

Dispensing substances into the environment is also envisaged in another product which is constructed from elements with a superhydrophilic coating, namely a graduation tower. In it, components provided with a porous superhydrophilic coating over which brine flows replace organic products, for example bundles of blackthorn, which is used in conventional graduation towers. Because of the high efficiency with respect to the size of the surface area over which liquid, in particular brine, flows, a miniaturized graduation tower can therefore be produced which is suitable for installation indoors, even in living spaces.

A general advantage of the porous silicon-based layer is that the properties of the layer, in particular the superhydrophilic properties, are retained over a long period of time and also when the environmental conditions change, even in cases of intermittent strong heating. The porous superhydrophilic layer can in principle be applied to a substrate in any form, either over the entire surface or in parts. In addition to applying the layer in geometric patterns, inscriptions, ornamentation or logos which are formed by the layer may also be applied, for example.

Some exemplary embodiments of the invention will now be described in more detail with the aid of the drawings, in which:

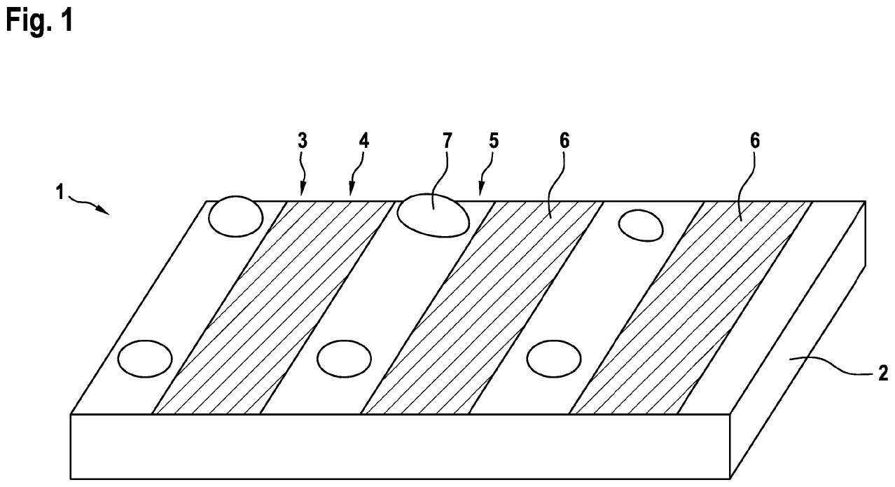

FIG. 1 shows a glass plate partially coated with a porous superhydrophilic silicon layer,

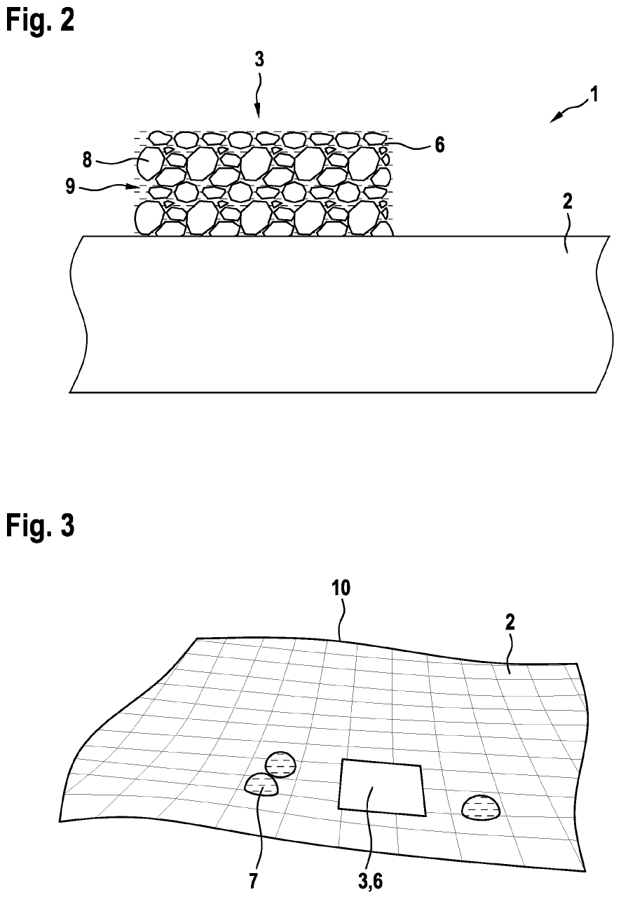

FIG. 2 shows a workpiece coated with a superhydrophilic coating in a diagrammatic sectional view,

FIG. 3 shows a sheet of paper with a sub-area coated with a superhydrophilic coating,

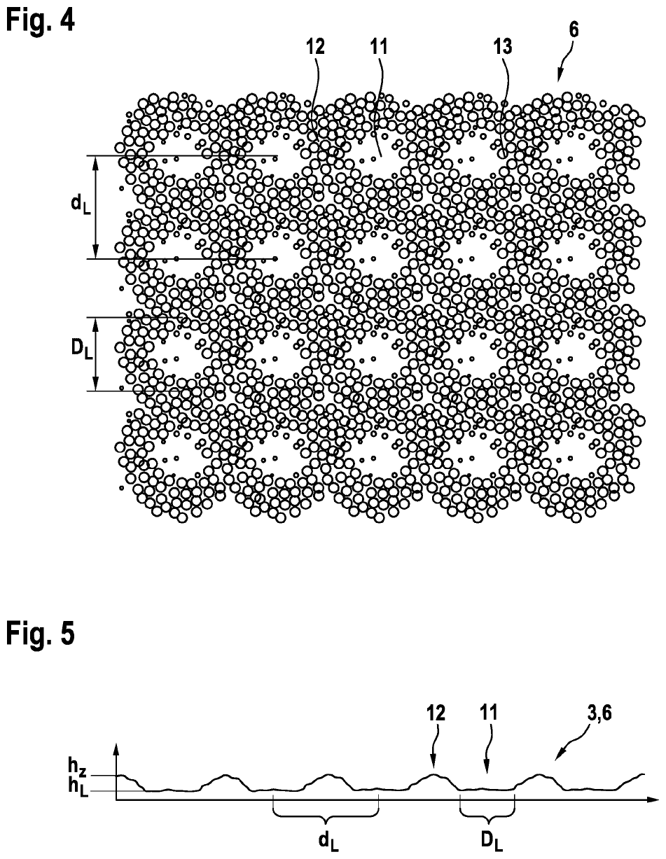

FIG. 4 shows the construction of a surface with a superhydrophilic coating in top view,

FIG. 5 shows a height profile of the coating of FIG. 4,

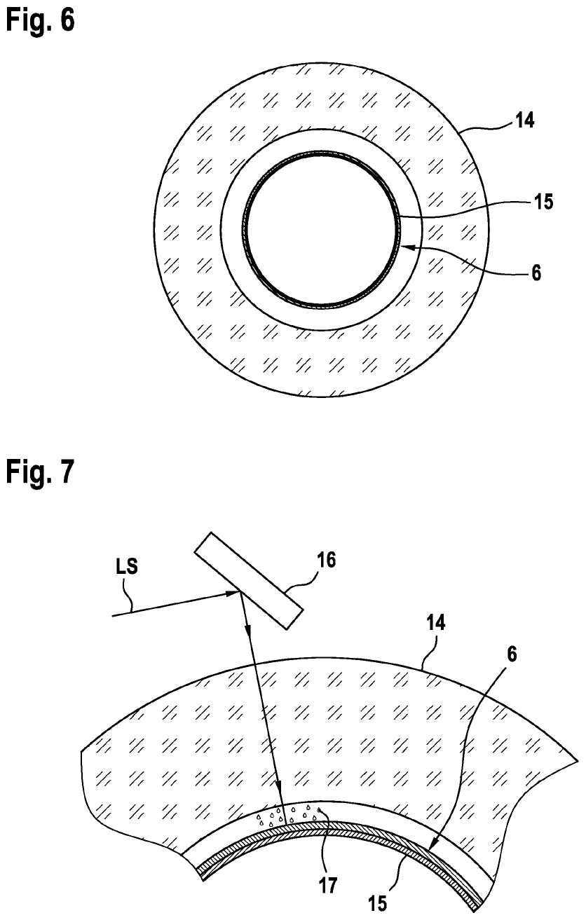

FIG. 6 shows an arrangement for coating the inside of a transparent tube,

FIG. 7 shows a detail of the arrangement of FIG. 6 during the coating procedure,

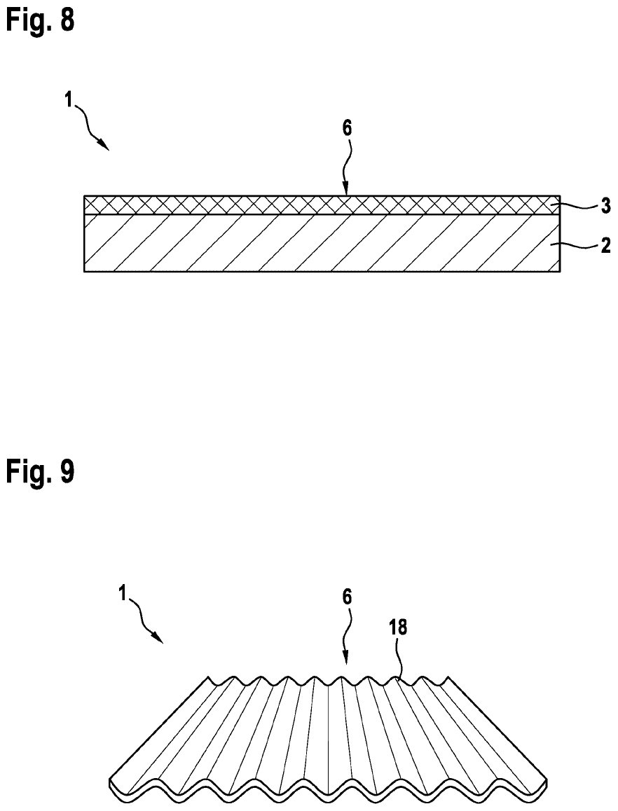

FIG. 8 shows an intermediate product for the production of a component of a graduation tower,

FIG. 9 shows a corrugated panel formed from the intermediate product of FIG. 8,

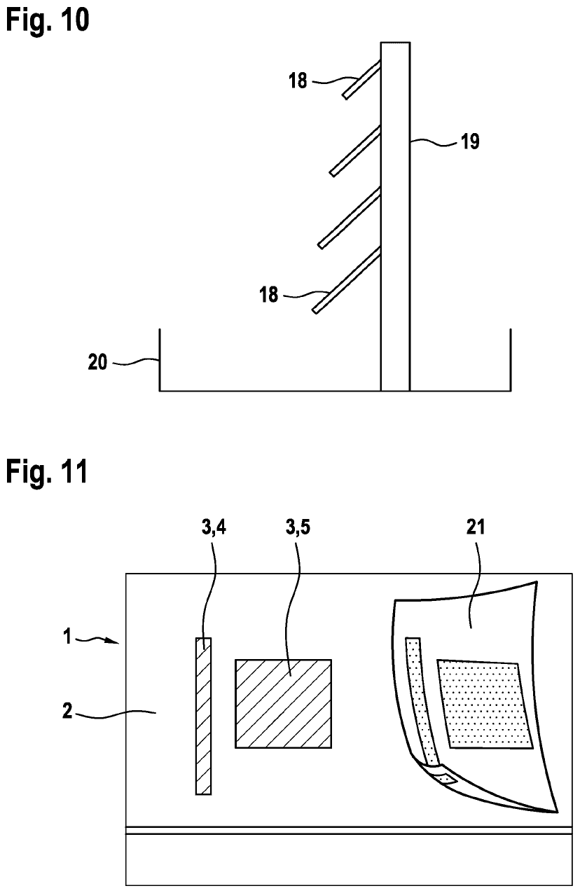

FIG. 10shows a graduation tower with a plurality of panels in accordance with FIG. 9, in a diagrammatic side view,

FIG. 11 shows a carrier film coated with silicon as well as a metallic substrate coated by laser transfer with the aid of this film,

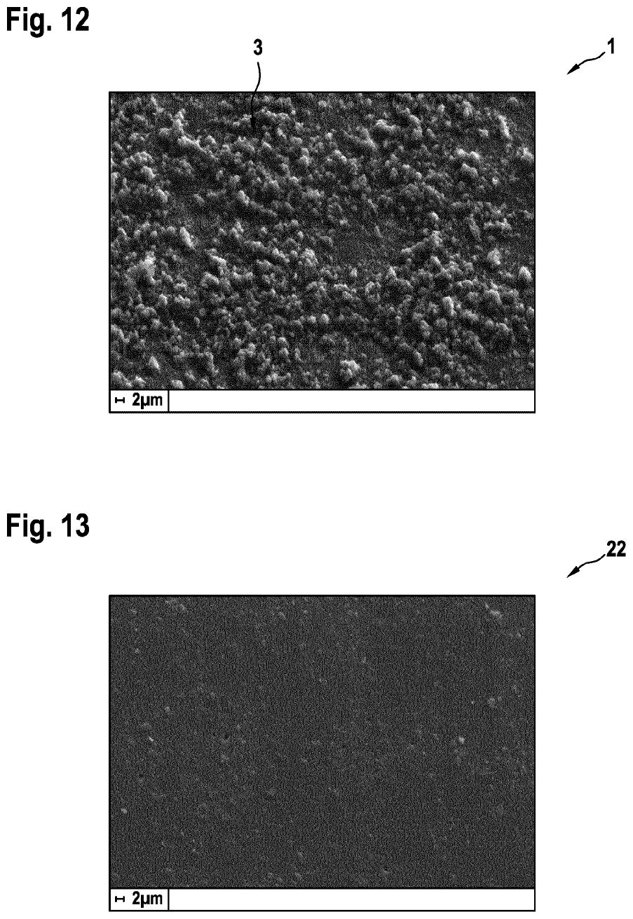

FIG. 12shows the surface of a workpiece with a superhydrophilic coating in an electron microscope image,

FIG. 13shows the surface of a comparative item in an image analogous to FIG. 12,

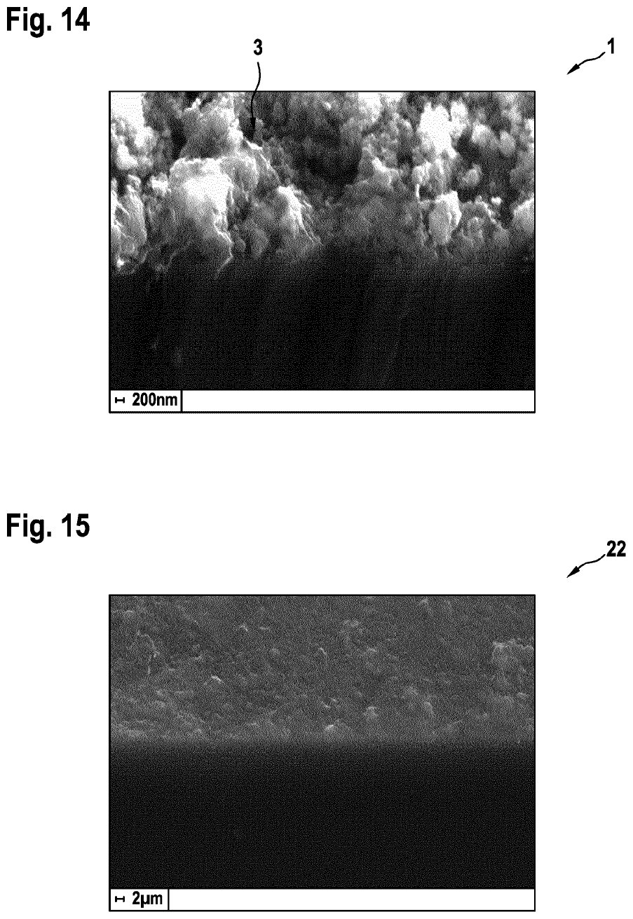

FIG. 14shows a cut surface of the workpiece of FIG. 12,

FIG. 15shows a cut surface of the comparative item of FIG. 13.

Unless otherwise indicated, the description below concerns all of the exemplary embodiments. Parts and geometrical structures which are comparable in principle are shown with the same reference numerals in all of the figures.

A workpiece which is generally indicated with the reference numeral 1 comprises a coating 3 which is located on a substrate 2, wherein different sub-areas 4, 5 may be coated or indeed uncoated in different manners. In all cases, there is a superhydrophilic silicon-based layer 6 on at least part of the surface of the substrate 2.

In the case of FIG. 1, the substrate 2 is a glass plate. In this case, the superhydrophilic layer 6 is in the form of stripes on the substrate 2. The glass is uncoated between the individual stripes formed by the layer 6. In these uncoated regions, water droplets 7 can be seen on the glass surface. If, in contrast, water is dripped onto the layer 6, then it spreads immediately. No droplets are formed; this is equivalent to a contact angle of zero degrees.

This superhydrophilic property of the layer 6 is illustrated in FIG. 2. The layer is constructed in a porous form from a solid 8, the major portion of which is silicon. Water 9 is taken up into pores of the solid 8. For the purposes of simplification, the thickness of the layer is shown in FIG. 2 as being constant.

The coating 3, which is completely or partially formed by the porous layer 6, is not just suitable for workpieces 1 with a smooth surface, but also for rough, in particular fibrous surfaces. In accordance with FIG. 3, this layer 6 is on a commercially available sheet of paper 10, for example. Furthermore, in this case too, individual water droplets 7 can be seen outside the coating 3. As in the case of FIG. 1, no water droplets would form on the coating 6. Rather, the water would be taken up by the coating 3 and dispersed within the coating 3.

In contrast to what can be seen in FIGS. 1 to 3, under microscopic examination, the porous layer 6 is not in any way constructed as a uniform surface. Reference is made to FIGS. 4 and 5 in this connection; they show the microscopic structure of the layer 6. Individual, approximately spot-like regions can readily be seen, which are disposed in a uniform rectangular pattern and are known as laser spots 11. The position of each laser spot 11 corresponds to the irradiation site for a laser pulse on a film coated with silicon which is used to coat the substrate 2 and is deposited on the substrate 2 during the coating procedure. The pattern of the laser spots 11 therefore reflects the rasterization of the laser pulses during the coating procedure.

Surprisingly, the layer 6 is thinnest in the region of the laser spot 11. The layer thickness in these regions, which are the light areas in FIG. 4, is indicated by h_{L}. Outside the laser spot 11 is a generally network-like intermediate region 12, which has a layer thickness h_{Z} which is at least three times the layer thickness h_{L}. The mean diameter of a laser spot 11 is indicated by D_{L}. The distance between the central points of two laser spots 11 is indicated by d_{L}. In the exemplary embodiment of FIG. 4, the mean diameter D_{L} is ca. 22 μm, while the mean distance d_{L} is approximately in the range from 33 μm to 43 μm. In the top view of FIG. 4, the intermediate region 12 appears as a structure of individual spot-like regions which are substantially smaller than the laser spots 11 and are known as nanospots 13. Each of these nanospots 13 can be interpreted as a splash which is generated during the coating process by the energy introduced by the laser and which is deposited on the substrate 2. In this regard, individual nanospots 13 have a slim, almost needle-like shape, wherein the nanospots 13 are perpendicular to the substrate 2, i.e. are orientated in the manner of lines which are normal to the surface. The ability of the layer 3 to take up and disperse water is essentially due to this structure of the intermediate region 12.

FIGS. 6 and 7 illustrate a special case of the laser-induced transfer of the layer 6 onto a substrate 2, in which it is a transparent tube 14. Firstly, a sleeve 15, on the outside of which the layer 6 of silicon is present, is introduced into the tube 14. The basic material of the sleeve 15 is not necessarily transparent in this exceptional case. The sleeve 15 in the tube 14 is inflated until the layer comes into contact with the inner wall of the tube 14. A gap between the sleeve 15 and the tube 14 which is visible in FIG. 7 is present merely to clarify the processes which are occurring. After positioning the sleeve 15 correctly, laser radiation LS, which in this case is deflected with the aid of a mirror 16, is directed onto the layer 6 located on the sleeve 15. This detaches substantially liquid material 17, i.e. droplets of silicon, from the surface of the sleeve 15 and deposits it on the inner wall of the tube 14. The coating 3 on the tube 14 which is produced thereby, i.e. the internal coating, has a construction of the type described with the aid of FIGS. 1 to 5, wherein any type of structuring, for example structuring in stripes, may be produced.

FIGS. 8 to 10 illustrate a further example of an application of the coating 3, namely using it in a graduation tower. Firstly, a flat, panel-shaped substrate 2 produced from metal, i.e. a sheet, is coated with the porous superhydrophilic layer 6. Next, the coated workpiece 1 is shaped and formed into a corrugated shape similar to a commercially available roofing panel, as can be seen in FIG. 9. A plurality of such corrugated panels 18, the tops of each of which are provided with the coating 3, is used in a graduation tower which comprises a support construction 19 on which the panels 18 are suspended and a collection basin 20. Instead of the panels 18, which have already been coated in the semi-finished product stage, rougher workpieces or workpieces with any type of structuring may be used, such as woven or knitted metal meshes, to which the porous superhydrophilic silicon layer 6 has been applied.

Brine which trickles over the coated panels 18 and/or over other coated workpieces come into contact with a very large surface area because of the microstructure of the porous layer 6 which has been described, before the fraction of the brine which is not dispersed into the environment arrives in the collection basin 20 and can be pumped back up; the capillary effect of the porous layer 6 may also be exploited in order to convey the brine.

In FIG. 11, in addition to a coated substrate 2, in this case produced from metal, a carrier film 21 can be seen which has been used to apply the coating 3. The carrier film, i.e. PET film in this case, has a thickness of 72 μm. As can be seen in FIG. 11, the carrier film 21 from which the layer transfer is made is significantly contorted. This is due to layer inherent stresses in the layer which are generated during vacuum coating, i.e. during the application of silicon to the carrier film 21. No such inherent stresses exist within the coating 3 constructed from porous silicon and deposited on the substrate 2.

As can also be seen in FIG. 11, the two flat rectangular or square regions from which silicon has been detached from the carrier film 21 by laser irradiation in order to transfer it onto the substrate 2 in the corresponding geometric form is not completely free of material which has been deposited on the carrier film, so that the corresponding regions are not completely transparent. The material remaining on the carrier film 21, i.e. silicon, is the result of the rasterized, not all-over, laser irradiation of the carrier film 21 which is produced from PET in this case.

The electron microscope images of FIGS. 12 to 15 show differences between the coating 3 produced in accordance with the method in accordance with the application (FIG. 12 and FIG. 14) and a comparative object 22, which is not claimed (FIG. 13 and FIG. 15). The comparative object 22 has been sputter-coated with silicon under vacuum. In the comparative object 22, a layered structure can be seen which is also seen with the coated carrier film 21. A comparison of FIGS. 12 and 14 on the one hand and FIGS. 13 and 15 on the other hand clearly shows the substantially greater roughness of the lasered coating 3 brought about by the laser transfer compared with the comparative object 22. The structure of the coating 3 with a very large specific surface area can be thought of as a solid powder.

### LIST OF REFERENCE NUMERALS

1 workpiece
2 substrate
3 coating
4 first sub-area
5 second sub-area
6 porous superhydrophilic layer
7 water droplets
8 solid
9 water taken up into the porous layer
10 sheet of paper
11 laser spot, raster dot, region
12 intermediate region
13 nanospot
14 transparent tube
15 sleeve
16 mirror
17 liquid material
18 corrugated panel
19 support construction
20 collection basin
21 carrier film
22 comparative object
d_{L} distance between two laser spots
D_{L} diameter of a laser spot
h_{L} height of a laser spot
h_{Z} height of an intermediate region
LS laser beam

1. A method for coating a substrate (2), with the following steps:
providing a transparent carrier film (21) which is coated with silicon,
positioning the side of the carrier film (21) coated with silicon on a surface of the substrate (2),
applying rasterized laser radiation to the coated carrier film (21), whereby silicon is detached from the carrier film (21) point by point and is deposited on the substrate (2) as a porous, rough, superhydrophilic layer (6).

2. The method as claimed in claim 1, characterized in that the laser radiation is directed onto the carrier film (21) in the form of individual raster dots (11), wherein each raster dot (11) has a standardized diameter (D_{L}) which is defined by the fact that 68.27% of the irradiated power lies inside a circle with the standardized diameter (D_{L}), and the mean distance (d_{L}) between two adjacent raster dots (11) is at least 125% and at most 250% of the standardized diameter (D_{L}).

3. The method as claimed in claim 1 or claim 2, characterized in that silicon predominantly in the liquid form is transferred onto the substrate (2) due to the laser radiation which acts on the carrier film (21) in the form of a rasterized pattern.

4. The method as claimed in one of claims 1 to 3, characterized in that for the material transfer from the carrier film (21) onto the substrate (2) to form a superhydrophilic layer, laser radiation with a power of 1.0 to 6.0 W, a frequency of 10 to 150 kHz, a laser speed of 500 to 4000 mm/s and a laser line separation of 0.02 to 0.3 mm is used.

5. The method as claimed in one of claims 1 to 4, characterized in that the irradiation of the carrier film (21) with laser radiation is carried out under atmospheric conditions.

6. The method as claimed in claim 5, characterized in that during the transfer from the carrier film (21) onto the substrate (2), silicon reacts with components of the air in a manner such that a layer (6) based on silicon is formed on the substrate (2) which has a proportion of oxygen of 1% to 10%, given as the % by weight.

7. The method as claimed in one of claims 1 to 6, characterized in that for the laser-induced transfer of material onto the substrate (2), a coating on the carrier film (21), namely a metallic layer a few nanometres thick, in particular a titanium layer with a maximum thickness of 10 nm, followed by a SiOₓN_{y} layer, is heated by a laser, wherein the SiOₓN_{y} layer contains proportions of oxygen and nitrogen atoms in the ranges 0.05<x<0.3 and 0.05<y<0.4 with respect to the number of silicon atoms.

8. The method as claimed in one of claims 1 to 7, characterized in that the carrier film (21) is irradiated with a laser beam with a wavelength of at least 300 nm and at most 1400 nm.

9. The method as claimed in one of claims 1 to 8, characterized in that parameters of the layer transferred from the carrier film (21) during the coating process are varied by adjusting laser parameters.

10. The method as claimed in claim 9, characterized in that both hydrophilic and also hydrophobic coating regions are produced by adjusting laser parameters during the coating process in a geometrically defined manner, in particular clocking and power of the laser as well as the duration of laser pulses and the distance of laser dots or lines.

11. The method as claimed in claim 10, characterized in that the at least one hydrophobic coating region is produced with a laser speed of less than 500 mm/s and a laser line distance of more than 0.3 mm.

12. The method as claimed in one of claims 1 to 11, characterized in that the porous rough superhydrophilic layer (6) is over-coated by utilising the same carrier film (21) repeatedly during one and the same coating procedure.

13. The method as claimed in claim 12, characterized in that in order to over-coat the superhydrophilic layer (6), which means increasing its layer thickness, a previously unused region of the carrier film (21) is employed, wherein in the case of multiple over-coating, for each over-coating procedure, previously unused regions of the carrier film (21) are exclusively employed.

14. The method as claimed in one of claims 1 to 13, characterized in that the porous rough superhydrophilic layer (6) is produced in combination with a hydrophobic indium tin oxide layer which is also deposited from a coated film by laser transfer.

15. The method as claimed in one of claims 1 to 13, characterized in that the porous, rough, superhydrophilic layer (6) is applied in combination with a PVD layer produced under vacuum in a later step of the method.

16. The method as claimed in one of claims 1 to 13, characterized in that the porous, rough, superhydrophilic layer (6) is applied in combination with a PVD layer transferred by laser in a later step of the method.

17. The method as claimed in one of claims 1 to 13, characterized in that the porous, rough, superhydrophilic layer (6) is only deposited onto a sub-area of the substrate (2), while a less hydrophilic surface region (5) of the substrate (2) compared with the porous layer (6) remains uncoated.

18. The method as claimed in one of claims 1 to 17, characterized in that the carrier film (21) is configured as a sleeve (15) the outside of which is coated with silicon, wherein this sleeve is introduced into a transparent tube (14) the inside of which is to be coated with a superhydrophilic layer and is inflated inside the tube (14), so that the silicon layer comes into contact with the inner wall of the tube (14), and wherein the transfer of silicon onto the inner wall of the tube (14) is carried out by laser radiation which passes from outside through the wall of the tube (14) and acts on the sleeve (15).

19. The method as claimed in one of claims 1 to 17, characterized in that the carrier film (21) is formed as a shrink sleeve which is coated on its inside with silicon and drawn over a workpiece to be coated, in particular a workpiece with a surface that cannot be unrolled, and which is brought into contact with the workpiece prior to laser transfer by heating.

20. A coating which is configured, on at least a first sub-area (4) of a substrate (2), as a porous superhydrophilic layer (6) deposited on the substrate (2) by rasterized laser radiation of a carrier coated with silicon and which has mutually separated regions (11) of lower roughness and thickness in a pattern corresponding to the rasterization of the laser beam, wherein an intermediate region (12) lying between these regions (11), which also forms part of said layer (6) and is also predominantly formed by silicon deposited on the substrate (2), has a comparatively large roughness and thickness.

21. The coating as claimed in claim 20, characterized in that the layer thickness (h_{Z}) of the intermediate region (12) is at least three times that of the layer thickness (h_{L}) in the regions (11) which are in the form of the rasterized pattern.

22. The coating as claimed in claim 20 or claim 21, characterized by a further sub-area (5) of the substrate (2) which is also at least predominantly coated with silicon, but has properties which are less hydrophilic compared with the superhydrophilic coating of the sub-area (4).

23. The coating as claimed in claim 22, characterized in that independently of how much coating parameters vary within one and the same layer (6), a boundary is formed between the superhydrophilic layer (6) and the further sub-area (5) at which a maximum gradient of at least one parameter, in particular the hydrophilicity, is present.

24. The coating as claimed in one of claims 20 to 23, characterized in that the superhydrophilic layer (6) has a porosity of at least 5%, and at most 40%.

25. The coating as claimed in one of claims 20 to 24, characterized in that the superhydrophilic layer (6) is in a regular pattern on the substrate (2), in particular in the form of stripes.

26. The coating as claimed in one of claims 20 to 25, characterized in that the contact angle when the superhydrophilic layer (6) is wetted with water is imaginary.

27. The coating as claimed in one of claims 20 to 26, characterized in that the superhydrophilic layer (6) is on paper (10) as the substrate.

28. The coating as claimed in one of claims 20 to 26, characterized in that the superhydrophilic layer (6) is located on at least one of the following components: membrane-electrode unit, electrode and bipolar plate of a fuel cell.

29. Use of a coating as claimed in claim 20 in a graduation tower.

30. Use of a coating as claimed in claim 20 for catalytic hydrogen production.

31. Use as claimed in claim 30, characterized in that the catalytic hydrogen generation is carried out without UV irradiation.
